(19) United States
(12) Patent Application Publication
(10) Pub. No.: US 2012/0153483 A1
(43) Pub. Date: Jun. 21, 2012

(54) BARRIERLESS SINGLE-PHASE INTERCONNECT

(76) Inventors: Rohan N. Akolkar, Hillsboro, OR (US); Florian Gstrein, Portland, OR (US); Daniel J. Zierath, Portland, OR (US)

(21) Appl. No.: 12/973,281

(22) Filed: Dec. 20, 2010

(51) Int. Cl. H01L 23/52; H01L 21/768

(52) U.S. Cl. 257/758; 438/637; 257/E23.141; 257/E21.577

(57) ABSTRACT

A method of forming an interconnect structure and an integrated circuit including the interconnect structure. The method includes: depositing a dielectric layer over a conductive layer; forming an opening in the dielectric layer to expose the conductive layer; forming a barrierless single-phase interconnect comprising a metal or compound having a melting point between a melting point of copper and a melting point of tungsten. Forming includes depositing a layer of metal or compound within the opening and on an upper surface of the dielectric layer Preferably, the barrierless single-phase interconnect comprises cobalt or a cobalt containing compound. Thus, an interconnect structure, including a via and associated line, is made up of a single-phase metal or compound without the use of a different material between the interconnect and the underlying dielectric, thus improving electrical performance and reliability and further simplifying the interconnect formation process.

### FIELD OF THE INVENTION

The disclosed embodiments relate generally to the manufacture of integrated circuit devices, and more particularly to methods of fabricating interconnects.

### BACKGROUND OF THE INVENTION

An integrated circuit (IC) device typically comprises a semiconductor die in which circuitry has been formed, this circuitry including a collection of circuit elements such as transistors, diodes, capacitors, resistors, etc. To provide electrical connections between the die and a next-level component (e.g., a package substrate), an interconnect structure is formed over a surface of the die, which may comprise a number of levels of metallization, each layer of metallization is separated from adjacent levels by a layer of dielectric material and interconnected with the adjacent levels by vias.

The conductors of any given metallization layer typically comprise a pattern of openings and vias, or other features, that are formed in the dielectric layer. The standard methodology today, first deposits a barrier layer to prevent metal migration into the surrounding dielectric material and to promote adhesion of the metal to the underlying ILD layer. Typical approaches use PVD or CVD Ti, Ta, TiN or TaN. Subsequently, openings and dual damascene vias are filled with an electrically conductive material, such as copper (although other technologies use tungsten or aluminum fill). The industry standard uses electroplated copper, which requires a relatively thin conductive seed layer first deposited, by chemical vapor deposition (CVD) process or physical vapor deposition (PVD) process. After seed layer formation, electroplated copper is then deposited in the unfilled portions, or gaps that remain, to completely fill opening and via and dual damascene features. After gap fill, a planarization process, such as chemical mechanical polishing (CMP), may be carried out to remove any excess metal material.

One disadvantage is that as devices shrink, the prior art exhibits high electrical resistance, poor feature fill and poor electromigration margin.

### BRIEF DESCRIPTION OF THE DRAWINGS

FIG. 1 is a block diagram illustrating a method embodiment;

FIGS. 2A-2F are schematic diagrams illustrating stages in practicing a method embodiment such as the method of FIG. 1; and

FIG. 3 is a schematic diagram illustrating an embodiment of an integrated circuit die that may be formed according to some embodiments.

### DETAILED DESCRIPTION OF THE INVENTION

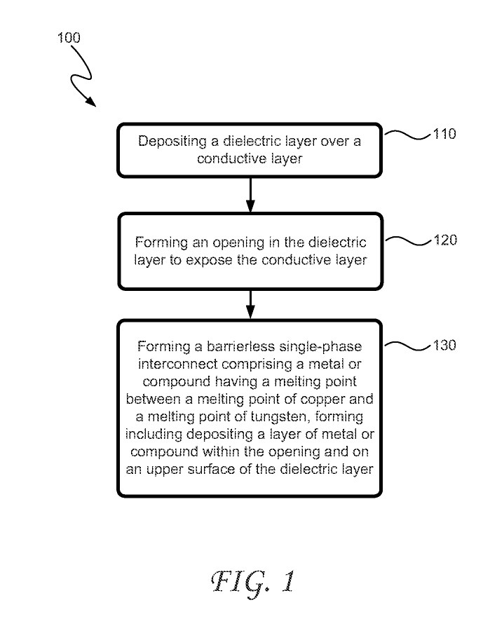

Illustrated in FIG. 1 is an embodiment of method 100 of fabricating a single-phase interconnect. At block 110, the method includes depositing a dielectric layer over a conductive layer. At block 120, the method includes forming an opening in the dielectric layer to expose the conductive layer, and at block 130, the method includes forming a barrierless single-phase interconnect comprising a metal or compound having a melting point between a melting point of copper and a melting point of tungsten, forming including depositing a layer of metal or compound within the opening and on an upper surface of the dielectric layer.

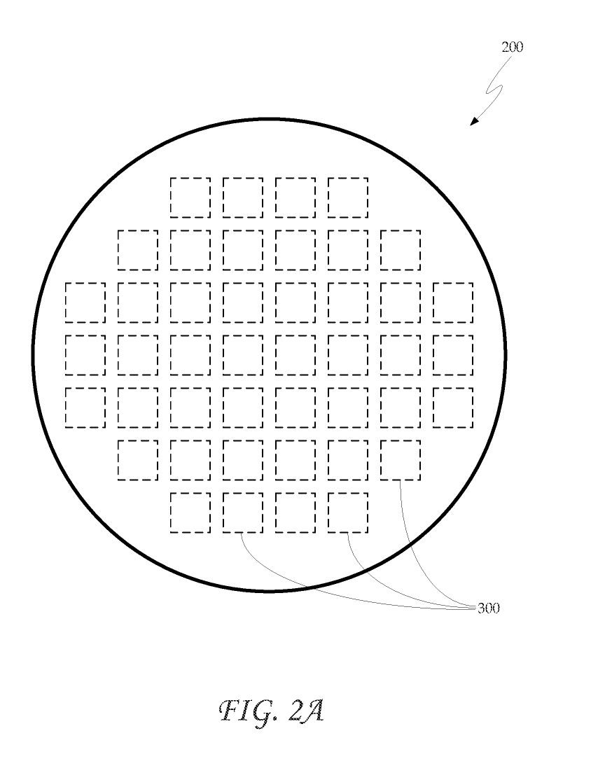

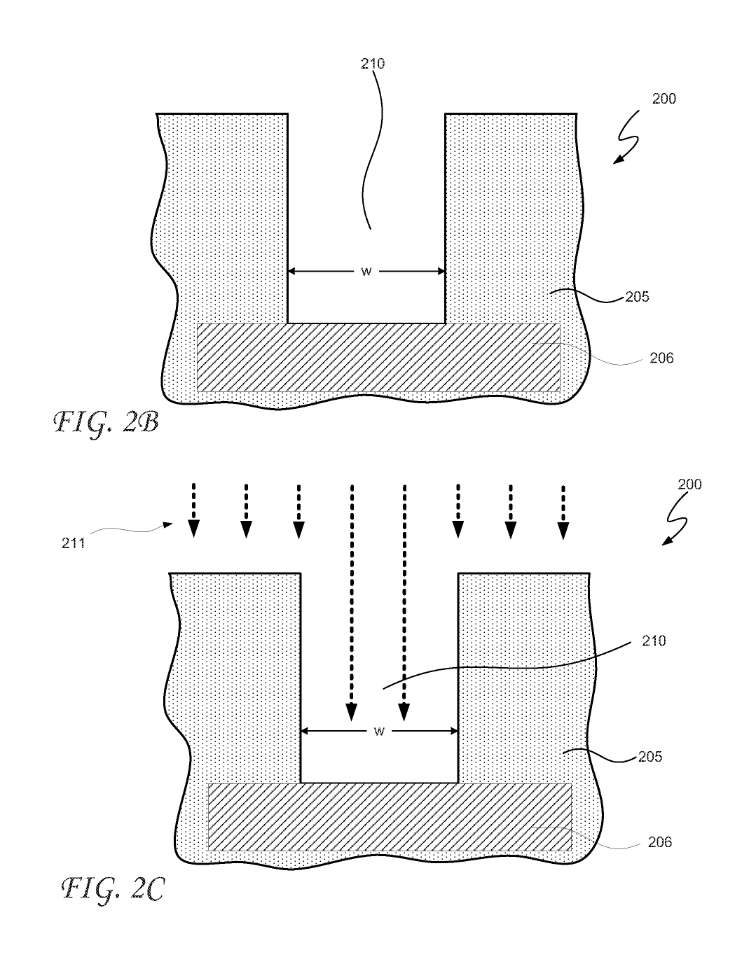

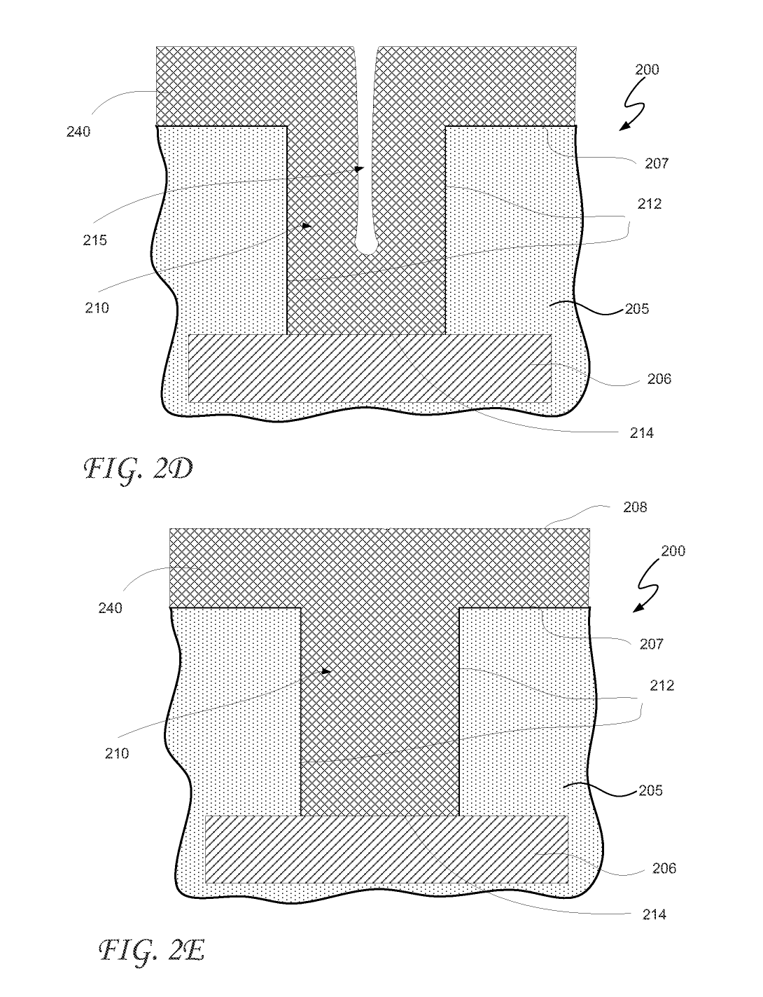

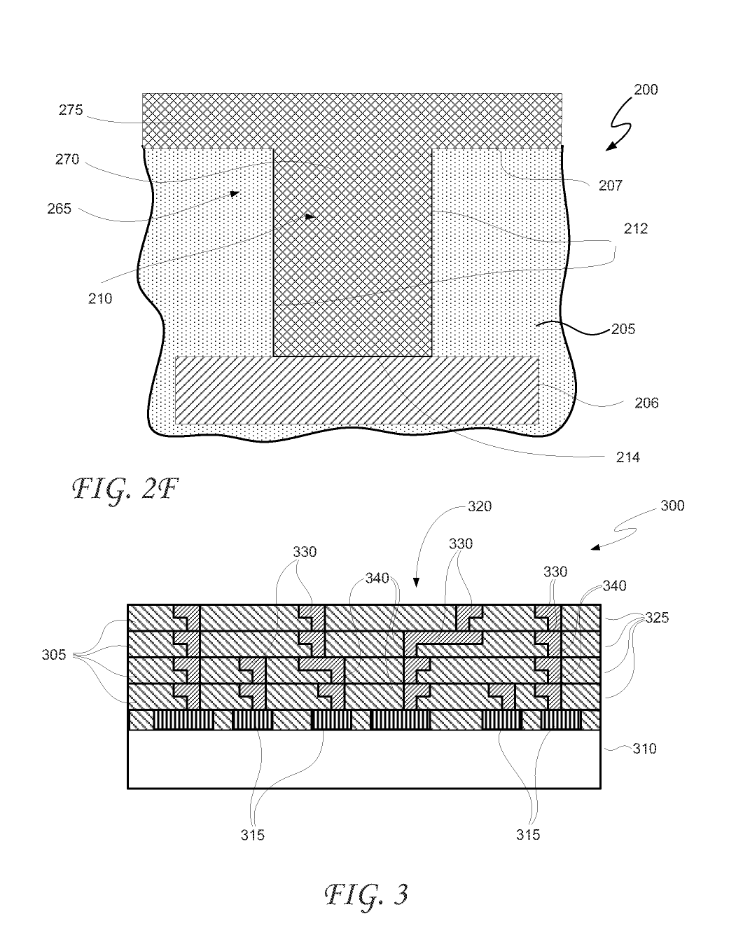

Referring first to FIGS. 2A and 2B, a substrate 200 is shown. The substrate 200 may comprise any substrate upon which a opening or other feature is formed that will ultimately be filled with a metal. In one embodiment, the substrate 200 comprises a semiconductor wafer (e.g., Si, SOI, GaAs, etc.) upon which integrated circuitry for a number of die 300 has been formed (see FIG. 2A), and wafer 200 is ultimately cut into these separate die. An interconnect structure will be formed over the device layer on this wafer (for each die 300), and this interconnect structure may include a number of levels of metallization. Each layer of metallization including lines is separated from adjacent levels by a layer of dielectric material, and each layer is interconnected with the adjacent layer(s) by vias. The metallization on each layer may comprise a number of conductors or lines that may route signal, power, and ground lines to and from the circuitry formed on the wafer. For ease of illustration, in FIGS. 2B-2F, only a portion of a dielectric layer 205 is shown that is provided on a conductive layer or line 206, and this dielectric layer and conductive layer may comprise layers in the interconnect structure that is formed over the device layer on the substrate 200.

With reference to FIG. 2C, an opening 210 has been formed in a dielectric layer 205 on substrate 200 to expose conductive layer 206. In one embodiment, the opening 210 comprises part of a pattern of openings that will form the conductors of one layer in the interconnect structure. The opening may be formed by any suitable process or combination of processes (e.g., photolithography followed by an etching process, etc.). In one embodiment, the opening 210 has a width (w) of up to 60 nm, and in a further embodiment, the opening has a width (w) of 30 nm or less. In yet another embodiment, the opening 210 has a width (w) of approximately 20 nm.

At this juncture, it should be noted that the disclosed embodiments are described in the context of a single opening formed in one dielectric layer of an interconnect structure. However, it should be understood that the disclosed embodiments are not so limited in application and, further, that the disclosed embodiments may find use with any structure having a feature that is to be filled with a metal. Furthermore, although a single opening in one dielectric layer is shown in the figures, it should be understood that the disclosed embodiments will typically be performed at the wafer level, and that such a wafer may include an interconnect structure for several hundred die, with the interconnect structure of each die perhaps containing thousands of conductors.

Referring to FIG. 2C, according to one embodiment, the upper surface of dielectric layer 205 may be pretreated using ion bombardment or a plasma process (generally shown by arrows 211) in order to enhance adhesion of a metal or compound thereto. For example, pre-treating may include using argon (Ar) ion bombardment, and the plasma process may include exposing the upper surface 207 of the dielectric 205 and the opening to silane, or to a mixture of hydrogen and helium or a mixture of hydrogen and Ar. It may be desirable to form a metal silicide film as a component of the fill in opening 210 to aide in adhesion and diffusion prevention properties. In this case, silane plasma pre-treatment could combine with the dielectric material and appropriate choice of a reactive metal (i.e., Co, Ni, Ti, Ta, Mo, etc) to form a silicide. Preferably, in an embodiment where a silane plasma is used, the reactive metal could include Co or Ni, as Co or Ni have lower resistance than Ti, Ta, Mo. Where the pretreatment process involves a plasma process, such as hydrogen/helium plasma or an argon plasma, it may be performed in a plasma chamber at a temperature ranging substantially between room temperature and about 300 degrees Celsius. The plasma process may be applied substantially between 20 to 60 seconds using an applied power substantially between 200-1000 Watts. In the alternative, an embodiment could include providing a conformal layer of a metal, such as for example, a layer of cobalt, and thereafter reacting the metal with another material to form the compound therewith, the compound then forming the single-phase interconnect. For example, silane could be used to treat a layer of deposited metal in order to form a compound therewith. Optionally, the metal or compound of layer 240, particularly in alloy form, may be doped with or contain for example small amounts of boron and/or phosphorus and/or tungsten to impart amorphous properties thereto.

Turning now to FIG. 2D, in one embodiment, a conformal layer 240 of a metal or compound may be deposited into the feature that has been formed in dielectric 205, and on an upper surface 207 of dielectric 205, the metal or compound having a melting point between that of copper and tungsten, that is, between about 1083° C. and about 3410° C. Preferably, the melting point is between about 1400° C. and about 2000° C. More preferably, the melting point is about 1495° C., corresponding to a melting point of cobalt. If a metal is used as the material of the conformal single-phase layer, it could include, for example, cobalt, nickel, palladium, platinum, rhodium, titanium, vanadium or zirconium. Preferably, the metal includes cobalt. If a compound is used as the material of the conformal single-phase layer, the compound could include, for example, CoSi2CoGe. It is noted “compound” as used herein encompasses alloys, although it is not limited to the same. Preferably, the compound is a compound including cobalt. Deposition of the conformal metal or compound layer is illustrated in FIG. 2D, where a metal or compound layer 240 has been deposited over the bottom 214 and side walls 212 of the opening 210, as well as over an upper surface 207 of the dielectric 205. For example, the conformal layer of metal or compound may be deposited by chemical vapor deposition (CVD), physical vapor deposition (PVD) or atomic layer deposition (ALD), or by way of electroplating using for example any of the above processes to first deposit a seed layer of metal or compound. The layer 240 may have any suitable thickness, and in one embodiment this layer has a thickness of between about 10 nm and about 25 nm for opening widths between about 20 nm and about 50 nm.

As seen in FIG. 2D, provision of the conformal layer of metal or compound may generate an incomplete fill of opening 210, creating a seam void 215 between facing walls of layer 240. According to an embodiment, as seen in FIG. 2E, and referring to block 120 of FIG. 1, a thermal anneal of the layer 240 may be effected to heal the seam void 215 at the center of feature 210 by either thermally reflowing the material or facilitating grain growth, in this way advantageously lowering interconnect resistance. For example, for a conformal layer 240 between 10 nm and 30 nm provided in a opening having an opening width of 20 nm up to about 60 nm, the layer 240 may be subjected to an anneal at between about 250° C. and about 450° C., for example for about 10 min up to about 2 hrs, and preferably at about 350° C. for about 10 min up to about 2 hours, Such an anneal may heal the seam independent of the thickness of layer 240.

Referring now to FIGS. 2E and 2F, excess material may be removed from an upper surface 208 of layer 240. As shown in FIG. 2F, excess material has been removed from the upper surface 208 of layer 240 shown in FIG. 2E, with portions of the layer 240 remaining in the opening 210. Material removal may be aimed in a well known manner at reducing a thickness of layer 240 resting on the upper surface 207 of dielectric 205, and/or at polishing the upper surface 208 of layer 240. Any suitable process may be used to remove excess material from layer 240. In one embodiment, for example, the excess material may be removed by chemical-mechanical polishing (CMP); however, other processes may also be suitable.

Regardless of whether or not a thermal anneal and/or excess material removal are performed depending on application needs, the provision of the metal or compound within the opening 210 and on the surface of the dielectric 205 may result in the provision of a barrierless single-phase interconnect 265 comprising a via 270 and a conductive line 275 made of the metal or compound, where the melting point of the metal or compound is between that of copper and tungsten. By “single-phase interconnect” what is meant in the context of embodiments is an interconnect, including a via and a line, where the via and the line are made of a one-piece or single material, either a metal or a compound. By “barrierless single-phase interconnect” what is meant in the context of embodiments is a single-phase interconnect that is provided without the deposition of a material different from the metal or compound of the interconnect between the interconnect and the underlying dielectric. For example, a single-phase interconnect” as used herein would not involve the use of a barrier layer, such as one containing Ti, Ta, TiN or TaN, deposited between it and the underlying ILD. It is noted that “a single-phase” as used herein does encompass a layer where the material may contain trace impurities, such as, by way of example, trace amounts of carbon or nitrogen that may be contained in a layer of cobalt obtained via CVD, or trace amounts of segregated dopants in a doped layer of metal. In addition, a line of a “single-phase interconnect” as used herein is not necessarily meant to be continuous, as long as it is made of a one-piece material with an underlying via.

Turning now to FIG. 3, illustrated is an embodiment of an integrated circuit die 300, which may be formed according to the disclosed embodiments. The die 300 comprises a semiconductor substrate 310, and circuitry 315 has been formed on a device layer on this substrate. The circuitry 315 may include a number of circuit elements (e.g., transistors, diodes, capacitors, resistors, etc.), as well as various signal lines that interconnect these elements. The substrate 310 may comprise any suitable semiconductor material, such as silicon (Si), silicon-on-insulator (SOI), gallium arsenide (GaAs), etc.

Disposed on the substrate 310 is an interconnect structure 320. The interconnect structure 320 includes a number of levels of metallization 325. Each level 325 comprises a number of interconnects, including conductive lines 330 and conductive vias 340. Each level of metallization is also disposed within and/or supported by a layer of dielectric material 305. The lines of each layer 325 are separated from the conductors in adjacent levels by one of the dielectric layers 305, and adjacent lines are electrically interconnected by the vias 340. The interconnects—e.g., lines 330 and vias 340—may comprise a metal or compound having a melting point between that of copper and tungsten, such as cobalt, nickel, palladium, platinum, rhodium, titanium, vanadium or zirconium, or compounds of the same. The dielectric layers 305 may comprise any suitable dielectric or insulating material, such as silicon dioxide (SiO₂), SiOF, carbon-doped oxide (CDO), a glass, or a polymer material. In one embodiment, the conductors 330 and vias 340 (or other interconnects) are formed according to any of the embodiments described above.

As the reader will appreciate, only a limited number of circuit elements 315, conductors 330, and vias 340 are shown in FIG. 3 for ease of illustration. However, as the reader will appreciate, the integrated circuitry 315 formed on substrate 310 may, in practice, includes tens of millions, or even hundreds of millions, of individual circuit elements and, further, that the interconnect structure 320 may include several hundred or even thousands of conductors 330 and/or vias 340 (or other interconnects). Thus, it should be understood that FIG. 3 is a simplified schematic representation of an integrated circuit die 300 that is presented merely as an aid to understanding the disclosed embodiments and, further, that no unnecessary limitations should be drawn from this schematic representation.

Advantageously, the provision of a layer of metal or compound as noted above achieves at least three notable functions: first, it provides interconnects (vias plus lines) having lower resistance than interconnects of the prior art, such as interconnects including barrier layers of tantalum, tantalum nitride or vias such as vias filled with tungsten, in this way improving the electrical performance of the system; second, it provides interconnects with better reliability than interconnects of the prior art by virtue of the higher melting point of the metal or compound used for the overall interconnect than interconnects of the prior art, which typically include copper (melting point of about 1083° C.), or possibly aluminum (an even lower melting point of about 660° C.), noting that the higher melting point of an interconnect according to embodiments affords better reliability due to its higher electromigration resistance; and third, it simplifies the interconnect formation process by allowing the provision of both the via material and the line material together, doing away with the necessity of providing the line and via in separate processes.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. A method of forming an interconnect structure comprising:
depositing a dielectric layer over a conductive layer;
forming an opening in the dielectric layer to expose the conductive layer;
forming a barrierless single-phase interconnect comprising a metal or compound having a melting point between a melting point of copper and a melting point of tungsten, forming including depositing a layer of metal or compound within the opening and on an upper surface of the dielectric layer.

2. The method of claim 1, wherein the metal or compound has a melting point between about 1400° C. and 2000° C.

3. The method of claim 2, wherein the metal or compound has a melting point of about 1600° C.

4. The method of claim 1, wherein the metal or compound comprising one of cobalt, nickel, palladium, platinum, rhodium, titanium, vanadium and zirconium.

5. The method of claim 1, further comprising doping the metal or compound.

6. The method of claim 1, wherein forming an opening comprises etching the opening.

7. The method of claim 1, wherein depositing includes performing electroplating and/or chemical vapor deposition, physical vapor deposition and atomic layer deposition.

8. The method of claim 1, further comprising annealing the layer of metal or compound after depositing.

9. The method of claim 8, wherein annealing comprises annealing at a temperature between 250° C. and about 450° C. for about 10 min up to about 2 hours.

10. The method of claim 9, wherein annealing comprises annealing at a temperature of 350° C. for about two hours.

11. The method of claim 1, further comprising removing excess material from an upper surface of the line.

12. The method of claim 11, wherein removing comprises polishing an upper surface of the line using chemical mechanical polishing.

13. The method of claim 1, further comprising pretreating an upper surface of the dielectric layer and walls of the opening using one of ion bombardment and a plasma process.

14. The method of claim 1, wherein the opening has a width between about 20 nm and about 60 nm.

15. An integrated circuit die including:
a substrate;
circuitry disposed on the substrate;
an interconnect structure disposed on the substrate, the interconnect structure including:
a conductive layer;
a dielectric layer disposed over the conductive layer and defining an opening therein exposing the conductive layer;
a barrierless single-phase interconnect comprising a metal or compound having a melting point between a melting point of copper and a melting point of tungsten.

16. The integrated circuit of claim 15, wherein the metal or compound has a melting point between about 1400° C. and 2000° C.

17. The integrated circuit of claim 16, wherein the metal or compound has a melting point of about 1600° C.

18. The integrated circuit of claim 15, wherein the metal or compound comprises one of cobalt, nickel, palladium, platinum, rhodium, titanium, vanadium and zirconium.

19. The integrated circuit of claim 15, wherein the opening has a width between about 20 nm and about 60 nm.

20. The integrated circuit of claim 15, wherein no seam exists in the metal or compound within the via.
